(19) United States
(12) Patent Application Publication
(10) Pub. No.: US 2010/0016168 A1
(43) Pub. Date: Jan. 21, 2010

(54) APPARATUS AND METHOD FOR TRANSPORTING CRYOGENICALLY COOLED GOODS OR EQUIPMENT

(76) Inventors: Andrew Farquhar Atkins, Oxon (GB); Peter Jonathan Clarke, Oxon (GB); Fiona Jane Smith, Oxon (GB)

Correspondence Address: SCHIFF HARDIN, LLP;PATENT DEPARTMENT, 233 S. Wacker Drive-Suite 6600, CHICAGO, IL, 60606-6473, US

(21) Appl. No.: 12/092,301

(22) PCT Filed: Aug. 22, 2006
(86) PCT No.: PCT/GB2006/050253

§ 371 Date: Nov. 25, 2008

(30) Foreign Application Priority Data
Nov. 1, 2005 (GB) 0522289.8

(51) Int. Cl. G01R 33/035; F17C 3/00; F25B 19/00; F17C 9/02; H01L 39/02

(52) U.S. Cl. 505/162; 62/51.1; 62/48.1; 62/51.1; 324/316

(57) ABSTRACT

In an apparatus and method for transporting cryogenically cooled goods or equipment, a cryostat containing the cryogenically cooled goods or equipment and partially filled with liquid cryogen is provided with a cryogenic refrigerator for active cooling; and auxiliary equipment sufficient to maintain the cryogenic refrigerator in operation, are all mounted on a transportable carrier such that the transportable carrier may be transported with the cryogenic refrigerator in operation without connection of any of the cryostat, refrigerator and auxiliary equipment to any supplies located off of the transportable carrier.

### BACKGROUND OF THE INVENTION

1. Field of the Invention

The present invention relates to methods and apparatus for transporting cryogenically cooled goods or equipment, such as superconducting magnets for magnetic resonance imaging (MRI) or nuclear magnetic resonance (NMR) imaging systems. In particular, it relates to such methods and apparatus for ensuring that such equipment arrives at its destination still cryogenically cooled, with limited consumption of cryogen material en route.

2. Description of the Prior Art

When a cryogenic system such as a superconducting magnet for magnetic resonance imaging (MRI) or nuclear magnetic resonance (NMR) imaging systems reaches its site of installation, it should arrive such that it can be deployed as rapidly as possible. The current approach is to place the magnet within a cryogen vessel filled with a liquid cryogen before departure. In the case of low temperature superconductor (LTS), this liquid cryogen would typically be liquid helium. For arrangements using high temperature superconductors (HTS), liquid neon, liquid nitrogen or liquid hydrogen could be used. The liquid cryogen is allowed to boil during transit, thereby ensuring a constant temperature whilst the liquid cryogen is present. The boiled off gaseous cryogen is vented to atmosphere, representing an economic loss and a waste of resources. The volume of cryogen initially provided within the system is defined such that there is sufficient fluid to ensure that some is left at the end of a certain period, such period being defined to encompass expected transit time. The period is typically set at 30 days. Once the system arrives at its installation site, additional liquid cryogen may be added to top up the cryostat to its operational fill level. Such topping up, however, is not for the purpose of cooling the system, since it will still be at its operating temperature, due to the continued presence of boiling cryogen.

The liquid cryogens employed in such methods are increasingly expensive, and in some cases are produced from non-renewable sources (e.g. helium, being derived from oil). For example, liquid helium presently costs almost GB£2 ( [symbol] 3, US$3) per liter. During transit of known superconducting magnets for magnetic resonance imaging (MRI) or nuclear magnetic resonance (NMR) imaging systems, up to 100 liters of liquid cryogen is typically lost during transport. However, with present cryostats carrying in the region of 1750 liters of cryogen, the potential for cryogen loss is much greater. A far greater cost risk is associated with the possibility that the whole volume of the cryogen may boil off: that the cryostat will boil dry and the cooled equipment will heat up to ambient temperature, for example 300K. In order to cool the equipment back to its required operating temperature, for example 4K, large volumes of liquid cryogen would need to be added, much of which would boil off to atmosphere in cooling the apparatus.

### SUMMARY OF THE INVENTION

The present invention aims to provide a method of shipping such cooled equipment which reduces the volume of liquid cryogen consumed.

Alternative solutions proposed include the following. The system may be shipped empty, at ambient temperature and cooled when it arrives. However, this would result in a very significant consumption of working cryogen at the installation site, as working cryogen is applied to cool the system to operating temperature. The cost, complexity and delay at the installation site render this option impractical. The cryogen vessel may be filled with an inexpensive, renewable, non-polluting cryogen such as liquid nitrogen. However, the system would need to be purged on site and then further cooled by application of working cryogen. This option is also costly and complex at the site of installation.

The present invention aims to prevent such loss of cryogen, while ensuring that the cooled equipment remains cooled throughout its journey, even though the journey itself may be prolonged beyond the normal maximum shipping time, which is currently in the region of 30 days.

The above object is achieved in accordance with the invention by an apparatus and method for transporting cryogenically cooled goods or equipment, wherein a cryostat containing the cryogenically cooled goods or equipment and partially filled with liquid cryogen is provided with a cryogenic refrigerator for active cooling; and auxiliary equipment sufficient to maintain the cryogenic refrigerator in operation, are all mounted on a transportable carrier such that the transportable carrier may be transported with the cryogenic refrigerator in operation without connection of any of the cryostat, refrigerator and auxiliary equipment to any supplies located off of the transportable carrier.

### DESCRIPTION OF THE DRAWINGS

The above, and further, objects, advantages and characteristics of the present invention will become more apparent by reference to the following description of certain embodiments thereof, given as of examples only, with reference to the accompanying drawings.

FIG. 1 shows a schematic drawing of a system according to an embodiment of the present invention.

FIG. 2 shows a schematic perspective view of an embodiment of the present invention.

### DESCRIPTION OF THE PREFERRED EMBODIMENTS

Current shipping methods involve initially filling the cryostat with cryogen to a level sufficient to maintain operating temperature for 30 days. The present invention aims to reduce this initial filling level to one sufficient to maintain operating temperature for a much shorter time period—for example, three days. Such should be sufficient to maintain the system at its operating temperature during air transit anywhere in the world. The volume of cryogen liquid placed in the system for transit may be reduced by up to 90%.

According to an aspect of the present invention, the cryostat containing the equipment to be cooled is provided with means for active refrigeration during transit. Such means may be active for most, or all, of the transit time. It is possible that operation of the active refrigeration means may not be permitted when the cryostat is carried by certain modes of transport, such as air, rail or sea. For this reason, liquid cryogen must be provided in sufficient volume to maintain the cooled equipment at operating temperature for the maximum predicted duration of such carriage, allowing time for customs clearance, until the cryostat may once again be accessed to restart active refrigeration.

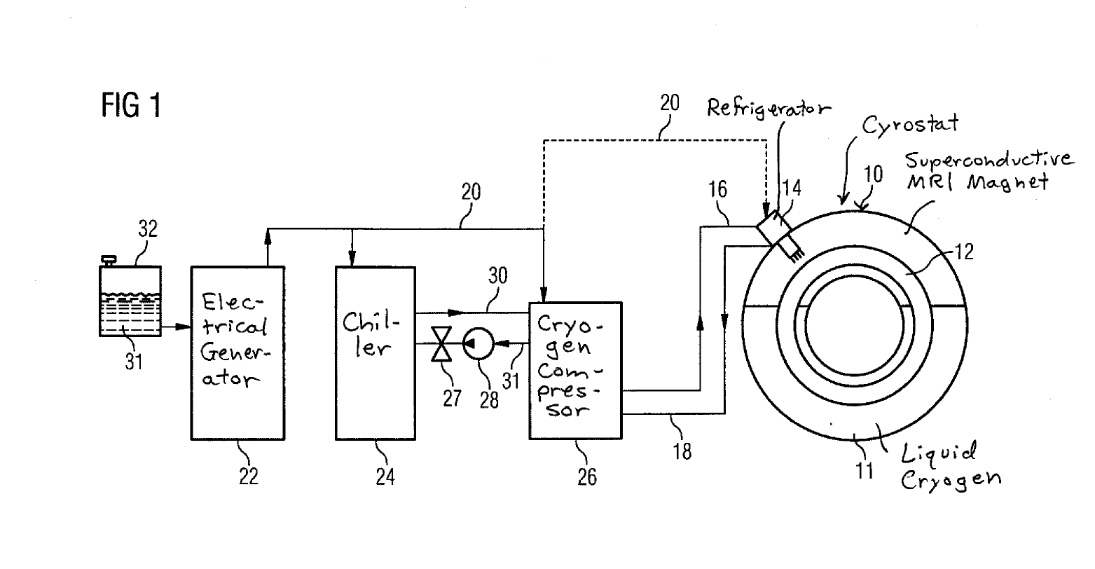

FIG. 1 shows a schematic drawing of a system according to an embodiment of the present invention A cryostat 10 containing a superconductive magnet 12 for MRI or NMR imaging and partially filled with liquid cryogen 11 is provided with a refrigerator 14 for active cooling. Such refrigerator may be of any of the known types of cryogenic refrigerators, such as a pulse tube refrigerator, a Gifford-McMahon refrigerator, or a Stirling cycle refrigerator. To enable the refrigerator to operate, a supply 16 of high pressure gas, and a gas return path 18, must be provided. This gas is typically helium, although other gases could be used, dependent upon the operating temperature of the cryostat. Depending of the type of refrigerator employed, an electrical supply 20 may also be required to the refrigerator. Accordingly, auxiliary equipment is provided to furnish the refrigerator with its required supplies. An electrical generator 22 is provided. This may conveniently be a diesel powered three-phase electrical generator providing 400V AC at 50 HZ at up to 20 kW. The electrical generator is connected to supply electrical power to a chiller 24 and a cryogen compressor 26. The chiller 24 cools and provides a supply of cooling fluid for cooling the cryogen compressor 26. The chiller 24 may be a model ICS TAE-020 of 9 kW cooling power, which consumes approximately 3 kW of electrical power. A forward cooling fluid flow path 30 and return feed cooling fluid path 31 are provided. In a certain embodiment, a valve 27 and flow meter 28 were provided to restrict the flow of water cooling fluid flow through the chiller to 8 litres per minute. The chiller may typically operate to cool a water cooling fluid flowing through it to a temperature of 10-20° C. While water may conveniently be employed as the cooling fluid, other cooling fluids may be used as appropriate.

The cryogen compressor 26 receives cooled cooling fluid 30 from the chiller 24, and electrical power 20 from the generator 22. It provides compressed cryogen gas supply 16 and a gas return path 18 to/from the cryogenic refrigerator 14. The cooled cooling fluid circuit serves to keep the compressor 26 cool. Further or alternative cooling could be provided using the material of the container as a heat sink. Cooling fluid and gas tanks, not shown in FIG. 1, may also be provided to maintain a supply of gas and cooling fluid for the chiller and the compressor. A supply of fuel 31, for example diesel fuel, is provided for the generator 22 in a tank 32.

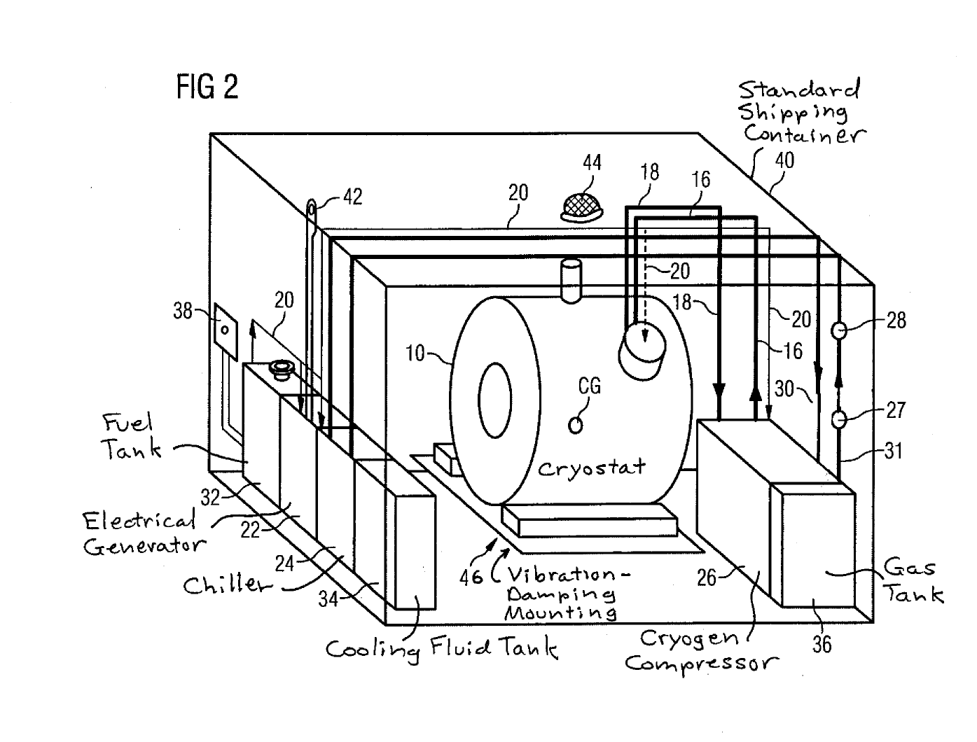

The whole system illustrated in FIG. 1, with its cooling fluid and gas tanks, is mounted on a transportable carrier. In a particularly preferred embodiment, the transportable carrier is in the form of a standard freight container, modified to provide an exhaust port for gases boiled off from the cryostat, and exhaust gases generated by the generator. It may also be required to provide an externally accessible switch (shown at 38 in FIG. 2), which may be lockable, in order to allow the generator to be turned off when necessary for transport.

FIG. 2 illustrates a perspective view of a standard shipping container 40 modified according to an embodiment of the present invention. Cooling fluid 34, gas 36 and fuel 32 tanks will also be provided within the container, to supply the chiller 24, gas compressor 26 and electrical generator 22 respectively. FIG. 2 provides only a very schematic representation, but those skilled in the art would easily design and incorporate suitable apparatus to fit in the container. Supply and return paths such as electrical supply 20, cooling fluid paths 30, 31 compressed gas 16, 18 are preferably routed along the walls and ceiling of the container 40 so as not to impede access for operators.

As illustrated, the cryostat 10 housing the cooled equipment, such as a superconducting magnet, is placed on a vibration reducing mounting 46, provided to limit horizontal acceleration applied to the cryostat. Such vibration reducing mountings are provided to restrain side-to-side oscillations. Vibration reducing mountings may also be provided for other components of the system. Such vibration reducing mounts serve to reduce the likelihood of damage to the system in transit, and ensure efficient operation of the various components during transit. They also serve to reduce the level of mechanical vibrations and acoustic noise transmitted to the body of the shipping container 40.

An exhaust vent 42 is provided in the wall or roof of the shipping container, to provide an exit path for exhaust gases from generator 22. A further vent 44 is also provided to enable boiled-off cryogen gas to escape from the container. Suitable screening or shielding should be provided to prevent ingress of foreign bodies through these vents 42, 44. Alternatively, the two gas exhaust paths may be combined within the container, and a single exhaust vent provided.

The use of a standard shipping container as the transportable carrier simplifies lifting and loading and unloading operations for transferring the system onto and off of lorries, trains, ships and aircraft. Such shipping containers are familiar sights all over the world, and provide a convenient storage and transport container for all manner of goods. The containers may be carried singly on lorries or railway carriages, or in large quantities on cargo ships. They may be loaded into aircraft cargo holds for air freight carriage. The containers are typically provided in standard length of 20 feet (6.1 m) or 40 feet (12.2 m). The containers are typically formed from corrugated sheet steel mounted on a frame of steel members. The shipping container employed in the present invention may be one such typical container, or may be a specially designed and constructed container which meets the standards of external dimensions and other required characteristics of such standard shipping containers. The chiller, generator and cryogen compressor will generate significant levels of heat within the container. Care must be taken to provide adequate ventilation for cooling the interior of the container. This may take the form of several openings in the container, preferably accompanied by a fan to assist exhaust of hot air.

In an alternative embodiment, an open ‘flat-rack’ container may be employed, preferably with a surrounding frame. A flat rack container is essentially an open frame the dimensions of a shipping container, and having all the advantages of ease of lifting and transport, but having no enclosed side or end panels. The use of a surrounding frame may be particularly appropriate for air transport. The use of this type of shipping container may enable the system to be transported in the cargo hold of an aircraft.

In one method according to the present invention, the cryostat 10 is loaded into a transportable container as described. The generator 22 is turned on, and active cooling operates during the length of the transit until the cryostat reaches its installation site. The cryostat is removed from the transportable container and connected to corresponding supplies at its installation site. The level of liquid cryogen 11 may be topped up if necessary. The cooled equipment 12 and the cryostat 10 may be very rapidly installed and brought into service.

In another method according to the present invention, the cryostat 10 is loaded into a transportable container as described. The generator 22 is turned on, and active cooling operates until the cryostat needs to be loaded onto an aircraft, ship or other transport which does not allow operation of the active refrigeration in transit. The generator is turned off, for example using switch 38, and the transportable container is placed on the transport. As the generator 22 is not operating, the liquid cryogen 11 will begin to boil off, so maintaining the cooled equipment 12 at the boiling point of the liquid. The cryostat 10 will remain in this condition until it is removed from the transport. The transportable carrier may then be placed on a lorry, for example, where active refrigeration is permitted. The generator 22 may be restarted and active refrigeration will be provided until the cooled equipment 12 reaches its installation site. The cryostat 10 is removed from the transportable container and connected to corresponding supplies at its installation site. The level of liquid cryogen 11 may be topped off if necessary. The cooled equipment 12 and the cryostat 10 may be very rapidly installed and brought into service. Since the duration of cooling by boiling cryogen is likely to last 3 days at the most, the volume and cost of boiled off cryogen is much less than the conventional method of cooling by boiling cryogen for the duration of the transit.

In a further method according to the present invention, two transportable containers as described are required. The cryostat 10 is loaded into a first transportable container. The generator is turned on, and active cooling operates until the cryostat needs to be loaded onto an aircraft, ship or other transport which does not allow operation of the active refrigeration in transit. The generator is turned off and the cryostat 10 housing the cooled equipment 12 is removed from the transportable container and is placed on the transport. The liquid cryogen will begin to boil off, so cooling the cooled equipment at the boiling point of the liquid. The cryostat 10 will remain in this condition until it is removed from the transport. The cryostat is then placed in the second transportable container and placed on a lorry, for example, where active refrigeration is permitted A generator 22 of the second transportable carrier is then started and active refrigeration will be provided until the cooled equipment reaches its installation site. The cryostat is removed from the second transportable container and connected to corresponding supplies at its installation site. The level of liquid cryogen 11 may be topped up if necessary. The cooled equipment 12 and the cryostat 10 may be very rapidly installed and brought into service. Since the duration of cooling by boiling cryogen is likely to last 3 days at the most, the volume and cost of boiled off cryogen is much less than the conventional method of cooling by boiling cryogen for the duration of the transit.

In embodiments described above, the boiled-off cryogen 11 is vented to atmosphere, while the electrical generator is powered by a fuel source such as a tank of diesel 32. A preferred embodiment of the invention may be employed in instances where the cryogen is flammable. For example, if the cryogen used is liquid hydrogen, the boiled off hydrogen may be used to power the generator. Such an arrangement may usefully provide a negative feedback arrangement: when the cryogen is boiling relatively rapidly, a plentiful supply of fuel is available for the generator, ensuring effective active cooling. If the cryogen is boiling relatively slowly, there will be a reduced supply of fuel available for the generator, in which case less active cooling may be required, saving on fuel consumption. Such embodiments have the added advantage of reducing, or eliminating, the emission of flammable gases to atmosphere. Burning of hydrogen to fuel the generator has the further advantage of producing no pollutants. The water vapour generated could be safely vented to atmosphere, or recondensed by a recondenser fed by the return cooling fluid supply to the cooler. Hydrogen or another fuel may be burned in a gas turbine to provide rotary power for the generator. As an alternative to burning fuel, the required electrical power may be provided by supplying hydrogen to power a fuel cell to generate electricity directly, without combustion. Transport of systems containing liquid hydrogen, or other flammable gases, may be forbidden on certain modes of transport. The transport of systems emitting flammable gases will be even more strictly controlled.

During an experiment, transport of a cryostat containing a superconducting magnet was arranged as described above. The cryostat was transported from Oxford, England to Erlangen, Germany and back in four days. On the outward journey, the generator was stopped for the duration of transport on a train through the channel tunnel. On the return journey, the cryostat was transported by sea ferry, and the generator was kept running. On departure, the magnet was filled to 74% capacity with liquid helium cryogen. On arrival in Erlangen, Germany, cryogen boil off had raised the pressure in the cryostat to about 2.5 psi (17 kPa) above atmospheric pressure. The cryostat was vented to release this pressure to atmospheric pressure. Some cryogen gas was lost at this point, reducing the cryogen fill level to 73%. At the end of the return journey, on arrival at Oxford, England, boil off of cryogen had again raised the pressure in the cryostat to about 2.5 psi (17 kPa) above atmospheric pressure. The cryostat was again vented to release this pressure to atmospheric pressure. Some cryogen gas was lost at this point, reducing the cryogen fill level to 71%.

This experiment showed that the increase in pressure within the cryostat was no more that would be expected when keeping the refrigerator running with the cryostat stationary. The helium loss on each leg of the journey was about 1%. This compares very favourably to the normal average loss of 6-7% over the same journey. The net reduction in cryogen consumption, 5%, represents a saving of 87.5 liters of cryogen for a 1750 litre capacity cryostat. A corresponding cost saving is realised on installation of the system, where a reduced volume of cryogen would be required for topping up the cryostat. Alternatively, a minimum cryogen level on arrival may be specified. This may, for example, be 60%. If a consumption of cryogen in transit can be reliably limited to 1%, the cryostat may be initially filled to only 61% capacity. To allow for unexpected delays and complications, it may be more prudent to fill the cryostat to, say, 64%. This would represent a reduction in cryogen fill at the point of departure equivalent to 10% cryogen fill, or 175 liters of cryogen for a 1750 liter capacity cryostat. The added costs of running the generator and depreciation of the transportable carrier and its equipment are estimated to be insignificant compared to such savings, provided that such shipments are frequently made.

If it is acceptable for only a very small quantity of cryogen to be present in the cryostat on arrival, only a small supply—say sufficient for three days' boiling—may be provided in the cryostat. This provides much reduced costs at the point of despatch, with correspondingly increased top-up costs at the point of arrival.

The financial savings in terms of cryogen consumption are complemented by an increased predictability of the state of the cryostat on arrival at its destination. With the conventional arrangement of filling with cryogen and allowing it to boil off during transit, there is a risk that delays in transit may cause the cryostat to boil dry, allowing the cooled equipment to heat up to ambient temperature. This then requires an expensive, inconvenient and time consuming re-cooling on arrival. Sufficient volumes of cryogen may not be readily available at the installation site. With the present invention, delays in transit will not cause significant loss of cryogen, provided that the generator is kept running. Use of a diesel powered generator is particularly convenient in this respect, since diesel fuel is readily available in most regions of the world and the cryostat may be maintained with an acceptable fill level virtually indefinitely, provided that the generator is kept running.

While the present invention has been described with particular reference to the transport of superconducting magnets for magnetic resonance imaging (MRI) or nuclear magnetic resonance (NMR) imaging, the present invention may usefully be applied to the transport of any cryogenically cooled goods or equipment. In some embodiments, it may be preferred to transport more than one cryostat per container, resulting in a further reduction in shipping costs.

Although modifications and changes may be suggested by those skilled in the art, it is the intention of the inventors to embody within the patent warranted heron all changes and modifications as reasonably and properly come within the scope of their contribution to the art.

We claim as our invention:

1. Apparatus for transporting cryogenically cooled goods or equipment, comprising
a cryostat containing the cryogenically cooled goods or equipment and partially filled with liquid cryogen provided with a cryogenic refrigerator for active cooling; and
auxiliary equipment sufficient to maintain the cryogenic refrigerator in operation; and
a transportable carrier on which said cryostat, said cryogenic refrigerator, and said auxiliary equipment are mounted, said transportable carrier being configured for transportation with the cryogenic refrigerator in operation without connection of any of the cryostat, refrigerator and auxiliary equipment to any supplies located off of the transportable carrier

2. Apparatus according to claim 1, wherein the auxiliary equipment comprises an electrical generator, a supply of fuel for the electrical generator, and a source of compressed gas required for operation of the cryogenic refrigerator.

3. Apparatus according to claim 2 wherein the supply of fuel for the electrical generator is provided by the liquid cryogen boiling to a gaseous state and being allowed to escape form the cryostat.

4. Apparatus according to claim 2 wherein the source of compressed gas comprises a compressor cooled by a circuit of cooling fluid.

5. Apparatus according to claim 4 further comprising a chiller for cooling the cooling fluid.

6. Apparatus according to claim 1 wherein the transportable carrier comprises at least one exhaust port for exhaust gases generated by the generator.

7. Apparatus according to claim 1 wherein the transportable carrier comprises an externally accessible switch for turning the generator off.

8. Apparatus according to claim 1 comprising a vibration reducing mounting on which the cryostat is mounted that limits horizontal acceleration applied to cryostat.

9. Apparatus according to claim 1 wherein the transportable carrier is formed as a standard shipping container.

10. Apparatus according to claim 1 wherein the cryogenically cooled goods or equipment comprises a superconducting magnet for magnetic resonance imaging systems.

11. A method for transporting cryogenically cooled goods or equipment, comprising:
providing an apparatus comprising a cryostat containing the cryogenically cooled goods or equipment and partially filled with liquid cryogen, a cryogenic refrigerator for active cooling, and auxiliary equipment sufficient to maintain the cryogenic refrigerator generator in operation;
operating the cryogenic refrigerator within said apparatus; and
transporting said apparatus to a destination, with the cryogenic refrigerator operating during transport.

12. A method for transporting cryogenically cooled goods or equipment, comprising
transporting said cryogenically cooled goods by a first means of transport to a first destination according to the method of claim 11;
halting operation of the cryogenic refrigerator;
transporting said apparatus to a second destination, with the cryogenic refrigerator inoperative during transport, the cooled goods or equipment being maintained at a cryogenic temperature by boiling of the liquid cryogen within the cryostat.

13. A method for transporting cryogenically cooled goods or equipment, comprising
transporting said cryogenically cooled goods to a second destination according to the method of claim 12;
recommencing operation of the cryogenic refrigerator;
transporting said apparatus to a third destination by a third means of transport, with the cryogenic refrigerator operating during such transport.

14. A method for transporting cryogenically cooled goods or equipment, comprising
transporting said cryogenically cooled goods or equipment in a cryostat, together with a cryogenic refrigerator for active cooling, by a first means of transport towards a first destination while operating the cryogenic refrigerator to actively cool said goods and equipment in the cryostat during said transport;
at the first destination, removing the cryostat containing the cryogenically cooled goods or equipment and partially filled with liquid cryogen from the apparatus;
transporting said cryostat by a second means of transport towards a second destination, with the cooled goods or equipment being maintained at a cryogenic temperature by boiling of the liquid cryogen within the cryostat;
at the second destination, placing the cryostat on a transportable carrier together with a cryogenic refrigerator to form a second apparatus; and
transporting said cryogenically cooled goods in said second apparatus by a third means of transport towards a third destination with the cryogenic refrigerator in operation without connection of the cryostat or the refrigerator to any supplies located off of the transportable carrier.

15. A method according to claim 11 further comprising the step of:
after arrival of the cryogenically cooled goods or equipment at a destination, removing the cryostat from the transportable container and connecting the cryostat to corresponding supplies at the destination, enabling the cryogenic refrigerator to be supplied by such supplies at the destination.

16. A method according to claim 11 comprising employing, as said auxiliary equipment, an electrical generator and the cryogen is flammable, and comprising using boiled off cryogen to power the electrical generator.

17. A method according to claim 11 comprising transporting a superconducting magnet for magnetic resonance imaging as said cryogenically cooled goods of equipment.

18. (canceled)
